(19) United States
(12) Patent Application Publication
(10) Pub. No.: US 2025/0185456 A1
(43) Pub. Date: Jun. 5, 2025

(54) ELECTROLUMINESCENT DISPLAY DEVICE

(71) Applicant: LG Display Co., Ltd., Seoul (KR)

(72) Inventors: Sora PARK, Paju-si (KR); HoSung KIM, Paju-si (KR)

(73) Assignee: LG Display Co., Ltd., Seoul (KR)

(21) Appl. No.: 18/825,895

(22) Filed: Sep. 5, 2024

(30) Foreign Application Priority Data
Dec. 5, 2023 (KR) 10-2023-0174962

(51) Int. Cl. H10K 50/18; H10K 50/19; H10K 101/30; H10K 101/40; H10K 102/00

(52) U.S. Cl. CPC H10K 50/181; H10K 50/19; H10K 2101/30; H10K 2101/40; H10K 2102/351

(57) ABSTRACT

An electroluminescent display apparatus can include a first electrode, a hole transporting layer disposed on the first electrode, a charge relaxation layer disposed on the hole transporting layer, an electron blocking layer disposed on the charge relaxation layer, a light emitting layer disposed on the electron blocking layer, an electron transporting layer disposed on the light emitting layer, and a second electrode on the electron transporting layer. The charge relaxation layer is disposed between the hole transporting layer and the electron blocking layer to remove a residual charge.

### CROSS-REFERENCE TO RELATED APPLICATION

This application claims priority to Korean Patent Application No. 10-2023-0174962, filed in the Republic of Korea on Dec. 5, 2023, the entire contents of which is hereby incorporated by reference into the present application.

### BACKGROUND

### Field

The present disclosure relates to an electroluminescent display device.

### Discussion of the Related Art

An electroluminescent display device includes a first electrode, a second electrode, and a light emitting layer disposed between the first electrode and the second electrode, and displays an image by emitting light from the light emitting layer by an electric field between the two electrodes.

The light emitting layer can include an organic material that generates an exciton by combining an electron and a hole and emits light while the generated exciton falls from an excited state to a ground state.

However, in some cases, the light emitting layer can emit some light due to a residual charge remaining in the organic material during a non-emission period, thereby deteriorating image quality.

### SUMMARY OF THE DISCLOSURE

The present disclosure has been made in view of the above problems and other limitations associated with the related art.

It is an object of the present disclosure to provide an electroluminescent display device capable of preventing a limitation of a light emitting layer emitting light due to a residual charge remaining in an organic material during a non-emission period.

In accordance with an aspect of the present disclosure, the above and other objects can be accomplished by the provision of an electroluminescent display device comprising a first electrode, a hole transporting layer disposed on the first electrode, a charge relaxation layer disposed on the hole transporting layer, an electron blocking layer disposed on the charge relaxation layer, a light emitting layer disposed on the electron blocking layer, an electron transporting layer disposed on the light emitting layer, and a second electrode on the electron transporting layer, wherein the charge relaxation layer is disposed between the hole transporting layer and the electron blocking layer to remove a residual charge.

In addition, in accordance with an aspect of the present disclosure, the above and other objects can be accomplished by the provision of an electroluminescent display device comprising a substrate including a first sub-pixel and a second sub-pixel, a circuit element layer disposed on the substrate, a first electrode on the circuit element layer, a hole transporting layer disposed on the first electrode and including a first hole transporting layer and a second hole transporting layer, a charge relaxation layer disposed on the hole transporting layer, an electron blocking layer disposed on the charge relaxation layer, a light emitting layer disposed on the electron blocking layer, an electron transporting layer disposed on the light emitting layer and a second electrode on the electron transporting layer, wherein the charge relaxation layer is disposed between the second hole transporting layer and the electron blocking layer in the first sub-pixel, and the charge relaxation layer is disposed between the first hole transporting layer and the electron blocking layer in the second sub-pixel.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic cross-sectional view of an electroluminescent display device according to an embodiment of the present disclosure.

FIG. 2 is a schematic diagram illustrating a forward bias driving mode of an electroluminescent display device according to an embodiment of the present disclosure.

FIG. 3 is a schematic diagram illustrating a reverse bias driving mode of an electroluminescent display device according to an embodiment of the present disclosure.

FIG. 4 is a schematic cross-sectional view of an electroluminescent display device according to another embodiment of the present disclosure.

FIG. 5 is a schematic cross-sectional view of an electroluminescent display device according to another embodiment of the present disclosure.

### DETAILED DESCRIPTION OF THE EMBODIMENTS

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion can be added unless ‘only’ is used. The terms of a singular form can include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions can be disposed between two other portions unless ‘just’ or ‘direct’ is used.

In the case of a description of a temporal relationship, for example, if the temporal precedence relationship is described as ‘after’, ‘subsequently’, ‘next to’, and ‘before’, or if it is not continuous unless ‘right’ or ‘direct’ is used.

It will be understood that, although the terms “first,” “second,” etc. can be used herein to describe various elements, these elements should not be limited by these terms. These terms are only used to distinguish one element from another, and may not define order or sequence. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship. Further, the term “can” encompasses all the meanings and coverages of the term “may.”

Hereinafter, the embodiment of the present disclosure will be described in detail with reference to the accompanying drawings. All the components of each display device or apparatus according to all embodiments of the present disclosure are operatively coupled and configured.

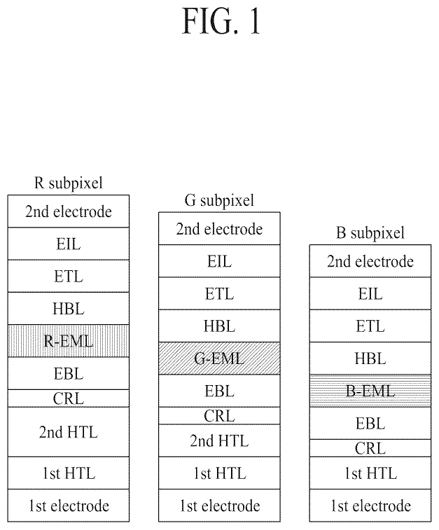

FIG. 1 is a schematic cross-sectional view of an electroluminescent display device according to an embodiment of the present disclosure.

As shown in FIG. 1, the electroluminescent display device according to the embodiment of the present disclosure includes a red sub-pixel (R sub-pixel), a green sub-pixel (G sub-pixel), and a blue sub-pixel (B sub-pixel).

Each of the red sub-pixel (R sub-pixel), the green sub-pixel (G sub-pixel), and the blue sub-pixel (B sub-pixel) includes a first electrode (1st electrode), a hole transport layer (1 st HTL, 2nd HTL), a charge relaxation layer (CRL), an electron blocking layer (EBL), an light emitting layer (R-EML, G-EML, B-EML), a hole blocking layer (HBL), an electron transporting layer (ETL), an electron injection layer (EIL), and a second electrode (2nd electrode).

In each of the red sub-pixel (R sub-pixel) and the green sub-pixel (G sub-pixel), the hole transporting layers (1st HTL, 2nd HTL) include a first hole transporting layer (1st HTL) and a second hole transporting layer (2nd HTL). Also, the first hole transporting layer (1st HTL) can be disposed in the blue sub-pixel (B sub-pixel), and the second hole transporting layer (2nd HTL) can not be disposed in the blue sub-pixel (B sub-pixel), but the present disclosure is not limited thereto.

A hole injection layer HIL can be additionally formed between the first electrode (1st electrode) and the first hole transport layer (1st HTL) in each of the red sub-pixel (R sub-pixel), the green sub-pixel (G sub-pixel), and the blue sub-pixel (B sub-pixel).

In each of the red sub-pixel (R sub-pixel), the green sub-pixel (G sub-pixel), and the blue-sub-pixel (B sub-pixel), the first electrode (1st electrode) can function as an anode of the electroluminescent display device, and the second electrode (2nd electrode) can function as a cathode of the electroluminescent display device.

When the electroluminescent display device according to the embodiment of the present disclosure is a top emission type, the first electrode (1st electrode) can include a reflective electrode, and the second electrode (2nd electrode) can include a transparent electrode or a translucent electrode. Alternatively, when the electroluminescent display device according to the embodiment of the present disclosure is a bottom emission type, the first electrode (1st electrode) can include a transparent electrode or a translucent electrode, and the second electrode (2nd electrode) can include a reflective electrode.

In each of the red sub-pixel (R sub-pixel) and the green sub-pixel (G sub-pixel), the first hole transporting layer (1st HTL) is disposed between the first electrode (1st electrode) and the second hole transporting layer (2nd HTL). Also, in the blue sub-pixel (B sub-pixel), the first hole transport layer (1st HTL) is disposed between the first electrode (1st electrode) and the charge relaxation layer (CRL).

In each of the red sub-pixel (R sub-pixel) and the green sub-pixel (G sub-pixel), the second hole transporting layer (2nd HTL) is disposed between the first hole transporting layer (1st HTL) and the charge relaxation layer (CRL).

The first hole transporting layer (1st HTL) can be formed of the same material in the red sub-pixel (R sub-pixel), the green sub-pixel (G sub-pixel), and the blue sub-pixel (B sub-pixel), but the present disclosure is not limited thereto.

The second hole transporting layer (2nd HTL) can be formed of the same material in the red sub-pixel (R sub-pixel) and the green sub-pixel (G sub-pixel), but the present disclosure is not limited thereto.

The first hole transporting layer (1st HTL) and the second hole transporting layer (2nd HTL) can include an organic material selected from the group consisting of 4,4′-N,N′-dicarbazolyl-biphenyl (CBP), N,N′-diphenyl-N,N′-bis(1-naphtyl)-1,1′-biphenyl-4,4″-diamine (α-NPD), N,N′-diphenyl-N,N′-bis(3-methylphenyl)-(1,1′-biphenyl)-4,4′-diamine (TPD), N,N′-bis(3-methylphenyl)-N,N′-bis(phenyl)-spiro (spiro-TPD), N,N′-di(4-(N,N′-diphenyl-amino)phenyl)-N,N′-diphenylbenzidine (DNTPD), 4,4′,4″-tris(N-carbazolyl)-triphenylamine (TCTA), polyaniline, polypyrrole, poly-phenylenevinylene, copper phthalocyanine, aromatictertiary amine, polynuclear aromatic tertiary amine, 4,4′-bis(p-carbazolyl)-1,1′-biphenyl compound, N,N,N′,N′-tetraarylbenzidine (PEDOT:PSS) and its derivatives, Poly-N-vinylcarbazole (PVK) and its derivatives, poly(p)phenylenevinylene and its derivatives such as poly[2-methoxy-5-(2-ethylhexyloxy)-1,4-phenylenevinylene] (MEH-PPV) or poly[2-methoxy-5-(3′,7′-dimethyloctyloxy)-1,4-phenylenevinylene] (MOMO-PPV), polymethacrylate and its derivatives, poly(9,9-octylfluorene) and its derivatives, poly(spiro-fluorene) and its derivatives, N,N′-di(naphthalene-1-yl)-N,N′-diphenyl-benzidine (NPB), tris(3-methylphenylphenylamino)-triphenylamine (m-MTDATA), poly(9,9′-dioctylfluorenyl-2,7-diyl)-co-(4,4′-(N-(4-sec-butylphenyl)diphenylamine (TFB), Poly(4-butylphenyl-dipnehyl amine) (poly-TPD), and spiro-NPB, but is not necessarily limited thereto.

In particular, the second hole transporting layer (2nd HTL) can include an organic material selected from the group consisting of PM6 (PBDB-T-2F), Y6-O, and P3HT, but is not limited thereto.

The first hole transporting layer (1st HTL) and the second hole transporting layer (2nd HTL) can be formed of the same material, but can be formed of different materials. For example, the second hole transporting layer (2nd HTL) can include an organic material having a Highest Occupied Molecular Orbital (HOMO) level lower than a HOMO level of the first hole transport layer (1st HTL).

The second hole transporting layer (2nd HTL) can be formed with an appropriate thickness for realizing a micro-cavity characteristic. For example, a thickness of the second hole transporting layer (2nd HTL) of the red sub-pixel (R sub-pixel) emitting long-wavelength light can be thicker than a thickness of the second hole transporting layer (2nd HTL) of the green sub-pixel (G sub-pixel) emitting medium-wavelength light. In the blue sub-pixel (B sub-pixel) emitting short-wavelength light, the micro-cavity characteristic can be implemented by the first hole transporting layer (1st HTL). Accordingly, the second hole transporting layer (2nd HTL) can not be disposed in the blue sub-pixel (B sub-pixel), but the present disclosure is not limited thereto.

In general, in order to amplify light through constructive interference by microcavity, a distance between the first electrode (1st electrode) and the second electrode (2nd electrode) is designed to be an integer multiple of s half wavelength (λ/2) of light emitted from the light emitting layer (R-EML, G-EML, and B-EML), and more accurately, it is designed to be the integer multiple of λ/2n in consideration of a refractive index (n) of an organic layer between the first electrode (1st electrode) and the second electrode (2nd electrode).

Therefore, a distance between the first electrode (1st electrode) and the second electrode (2nd electrode) in the red sub-pixel (R sub-pixel) emitting red light having the longest wavelength can be the longest, and a distance between the first electrode (1st electrode) and the second electrode (2nd electrode) in the blue sub-pixel (B sub-pixel) emitting blue light having the shortest wavelength can be the shortest.

A difference in the thickness of the hole transporting layers (1st HTL, 2nd HTL) can occur between the red sub-pixel (R sub-pixel), the green sub-pixel (G sub-pixel), and the blue sub-pixel (B sub-pixel). Accordingly, a distance from the first electrode (1st electrode) of the red sub-pixel (R sub-pixel) to the second electrode (2nd electrode) of the red sub-pixel (R sub-pixel) can be longer than a distance from the first electrode (1st electrode) of the green sub-pixel (G sub-pixel) to the second electrode (2nd electrode) of the green sub-pixel (G sub-pixel). Also, the distance from the first electrode (1st electrode) of the green sub-pixel (G sub-pixel) to the second electrode (2nd electrode) of the green sub-pixel (G sub-pixel) can be longer than a distance from the first electrode (1st electrode) of the blue sub-pixel (B sub-pixel) to the second electrode (2nd electrode) of the blue sub-pixel (B sub-pixel).

In each of the red sub-pixel (R sub-pixel) and the green sub-pixel (G sub-pixel), the charge relaxation layer (CRL) is disposed between the second hole transporting layer (2nd HTL) and the electron blocking layer (EBL). Also, in the blue sub-pixel (B sub-pixel), the charge relaxation layer (CRL) is disposed between the first hole transporting layer (1st HTL) and the electron blocking layer (EBL).

When driving the electroluminescent display device, there is a period in which the light emitting layers (R-EML, G-EML, B-EML) emit light by an electric field between the first electrode (1st electrode) and the second electrode (2nd electrode), and a period in which the light emitting layers (R-EML, G-EML, B-EML) do not emit light. In this case, even though it is in a non-emission period, there can be a problem in that the light emitting layers (R-EML, G-EML, and B-EML) partially emits light due to a residual charge remaining between the first electrode (1st electrode) and the second electrode (2nd electrode).

The charge relaxation layer (CRL) can serve to remove the residual charge. Specifically, when reverse bias is applied to the electroluminescent display device, the hole as the residual charge is allowed to exit through the charge relaxation layer (CRL), thereby extinguishing the residual charge. Accordingly, a problem in which the light emitting layers (R-EML, G-EML, and B-EML) emit light during the non-emission period can be prevented. That is, the charge relaxation layer (CRL) can function as a quencher layer for extinguishing the residual charge.

Also, the residual charge, particularly, the residual hole can occur at an interface between the second hole transporting layer (2nd HTL) and the electron blocking layer (EBL). In this case, even after a reverse bias period such as an anode reset period, there is a problem in that light emission occurs due to the residual charge, for example, during a next frame period of the reverse bias period or a switch-off state.

According to the embodiment of the present disclosure, by adding the charge relaxation layer (CRL) between the second hole transporting layer (2nd HTL) and the electron blocking layer (EBL), the residual charge at the interface between the second hole transporting layer (2nd HTL) and the electron blocking layer (EBL) is extinguished, Accordingly, a problem in which light emission occurs in the next frame period of the reverse bias period or the switch-off state can be prevented. Therefore, in each of the red sub-pixel (R sub-pixel) and the green sub-pixel (G sub-pixel), a lower surface of the charge relaxation layer (CRL) can be in contact with an upper surface of the second hole transporting layer (2nd HTL), and an upper surface of the charge relaxation layer (CRL) can be in contact with a lower surface of the electron blocking layer (EBL).

Accordingly, it can be desirable for the charge relaxation layer (CRL) to have a determined HOMO (Highest Occupied Molecular Orbital) level, a LUMO (Lowest Unoccupied Molecular Orbital) level, and a band gap energy, which will be described later.

In addition, there should not be a problem in charge transfer due to the charge relaxation layer (CRL) when the display device is driven by applying forward bias. Accordingly, it can be desirable to form a thickness of the charge relaxation layer (CRL) thin in the range of 1 nm to 3 nm to enable tunneling injection of a charge, such as a hole.

Specifically, by forming the thickness of the charge relaxation layer (CRL) to be thin in the range of 1 nm to 3 nm, it does not have any effect during forward bias. And, when reverse bias is applied, residual charges (holes) can disappear or residual charge density can be reduced since the residual charges (holes) meet with free electrons present in the charge relaxation layer (CRL). Accordingly, it is possible to improve the stability of the device by reducing residual charges flowing into the light emitting layer (R-EML, G-EML, and B-EML).

In each of the red sub-pixel (R sub-pixel), the green sub-pixel (G sub-pixel), and the blue sub-pixel (B sub-pixel), the electron blocking layer (EBL) is disposed between the charge relaxation layer (CRL) and the light emitting layers (R-EML, G-EML, B-EML).

The electron blocking layer (EBL) can be formed of the same material in the red sub-pixel (R sub-pixel), the green sub-pixel (G sub-pixel), and the blue sub-pixel (B sub-pixel), but the present disclosure is not limited thereto.

The electron blocking layer (EBL) can be formed of TCTA, Tris[4-(diethylamino)phenyl] amine, N-(biphenyl-4-yl)-9,9-dimethyl-N-(4-(9-phenyl-9H-carbazole-3-yl)phenyl)-9H-fluorene-2-amine, tri-p-tolylamine (TAP), MTDATA, mCP, mCBP, TPD, CuPC, DNTPD, and/or TDAPB, but the present disclosure is not limited to.

In each of the red sub-pixel (R sub-pixel), the green sub-pixel (G sub-pixel), and the blue sub-pixel (B sub-pixel), the light emitting layers (R-EML, G-EML, B-EML) are disposed between the electron blocking layer (EBL) and the hole blocking layer (HBL).

The light emitting layers (R-EML, G-EML, B-EML) can include a fluorescent or phosphorescent organic light emitting material that emits red, green, or blue light.

The light emitting layers (R-EML, G-EML, B-EML) can include a host and a dopant. The host can be selected from the group consisting of Tris(8-hydroxyquinoline)aluminum (Alq3), TCTA, PVK, 4,4′-bis(N-carbazolyl)-1,1′-biphenyl (CBP), 4,4′-Bis(9-carbazolyl)-2,2′-dimethylbiphenyl (CDBP), 9,10-di(naphthalene-2-yl) anthracene (ADN), 3-tert-butyl-9,10-di(naphtha-2-yl) anthracene (TBADN), 2-methyl-9,10-bis(naphthalene-2-yl) anthracene (MADN), 1,3,5-tris(N-phenylbenzimidazole-2-yl)benzene (TPBi), distyrylarylene (DSA), mCP, and (1,3,5-tris)benzene (1,3,5-tris) yl)benzene (TCP), but the present disclosure is not limited thereto.

The dopants included in the red light emitting layer (R-EML) include organic or organometallic complexes such as 5,6,11,12-tetraphenylnaphthalene (Rubrene), Bis(2-benzo[b]-thiophene-2-yl-pyridine) (acetylacetonate) iridium (III) (Ir(btp)2(acac)), Bis[1-(9,9-diemthyl-9H-fluorn-2-yl)-isoquinoline](acetylacetonate) iridium (III) (Ir(fliq)2(acac)), Bis-(2-phenylquinoline) (2-(3-methylphenyl)pyridinate)irideium(III) (Ir(phq)2typ), and irideium(III) bis(2-(2,4-difluorophenyl) quinoline) picolinate (FPQIrpic) but the present disclosure is not limited to.

The dopants included in the green light emitting layer (G-EML) include organic or organometallic complexes such as N,N′-dimethyl-quinacridone (DMQA), 9,10-bis[N,N-di-(p-tolyl)amino]anthracene (TTPA), 9,10-bis[phenyl(m-tolyl)-amino]anthracene (TPA), bis(2-phenylpyridine) (acetylacetonate) iridium (III) (Ir(ppy)2(acac)), fac-tris(phenylpyridine)iridium(III) (fac-Ir(ppy)3), and tris[2-(p-tolyl)pyridine]iridium(III) (Ir(mppy)3), but the present disclosure is not limited to.

The dopants included in the blue light emitting layer (B-EML) include organic or organometallic complexes such as diphenyl-[4-(2-[1,1; 4,1]terphenyl-4-yl-vinyl)-phenyl]-amine (BD-1), 4,4′-bis[4-(di-p-tolylamino) styryl]biphenyl (DPAVBi), 2,5,8,11-tetra-tert-butylpherylene (TBPe), bis(3,5-difluoro-2-(2-pyridyl)phenyl-(2-carbozylpyridyl)iridium(III) (FirPic), mer-tris(1-phenyl-3-methylimidazolin-2ylidene-C,C2′)iridium(III) (mer-Ir(pmi)3), and tris(2-(4,6-difluorophenyl)pyridine)iridium(III) (Ir(Fppy)3), but the present disclosure is not limited to.

In each of the red sub-pixel (R sub-pixel), the green sub-pixel (G sub-pixel), and the blue sub-pixel (B sub-pixel), the hole blocking layer (HBL) is disposed between the light emitting layer (R-EML, G-EML, B-EML) and the electron transport layering (ETL).

The hole blocking layer (HBL) can be formed of the same material in the red sub-pixel (R sub-pixel) and the green sub-pixel (G sub-pixel), but the present disclosure is not limited thereto.

The hole blocking layer (HBL) can be selected from the group consisting of BCP, BAlq, Alq3, PBD, spiro-PBD, Liq, bis-4,6-(3,5-di-3-pyridylphenyl)-2-methylpyrimidine (B3PYMPM) and/or Oxybis(2,1-phenylene)bis(diphenyl phosphine oxide) (DPEPO), but the present disclosure is not limited thereto.

The hole blocking layer (HBL) can be omitted.

In each of the red sub-pixel (R sub-pixel), the green sub-pixel (G sub-pixel), and the blue sub-pixel (B sub-pixel), the electron transport layer (ETL) is disposed between the hole blocking layer (HBL) and the electron injection layer (EIL).

The electron transport layer (ETL) can be formed of the same material in the red sub-pixel (R sub-pixel) and the green sub-pixel (G sub-pixel), but the present disclosure is not limited thereto.

The electron transport layer (ETL) can include an organic material such as an imidazole-based compound, an oxazole-based compound, an isoxazole-based compound, a triazole-based compound, an isothiazole-based compound, an oxadiazole-based compound, a thiadiazole-based compound, a phenanthroline-based compound, a perylene-based compound, a benzothiazole-based compound, a benzimidazole-based compound, a pyrene-based compound, a triazine-based compound or an aluminum complex. As a specific example, the electron transport layer (ETL) can be selected from the group consisting of 3-(biphenyl-4-yl)-5-(4-tertbutylphenyl)-4-phenyl-4H-1,2,4-triazole (TAZ), bathocuproine, 2,9-dimethyl-4,7-diphenyl-1,10-phenanthroline (BCP), 2-biphenyl-4-yl-5-(4-t-butylphenyl)-1,3,4-oxadiazole (PBD), lithium quinolate (Liq), 2,2′,2″-(1,3,5-Benzinetriyl)-tris(1-phenyl-1-H-benzimidazole (TPBi), 2-[4-(9,10-Di-2-naphthalenyl-2-anthracenyl)phenyl]-1-phenyl-1H-benzimidazole, Tris(8-hydroxyquinoline)aluminum (Alq3), (bis(2-methyl-8-quninolinato)-4-phenylphenolatealuminum (III) (Balq), bis(2-methyl-quinolinato)(tripnehylsiloxy) aluminum (III) (Salq), and tris-phenyl quinoxaline (TPQ).

In each of the red sub-pixel (R sub-pixel), the green sub-pixel (G sub-pixel), and the blue sub-pixel (B sub-pixel), the electron injection layer (EIL) is disposed between the electron transport layer (ETL) and the second electrode (2nd electrode).

The electron injection layer (EIL) can be formed of the same material in the red sub-pixel (R sub-pixel) and the green sub-pixel (G sub-pixel), but the present disclosure is not limited thereto.

The electron injection layer (EIL) can include a material doped with fluorine on a metal such as Al, Cd, Cs, Cu, Ga, Ge, In, and Li. Alternatively, the electron injection layer (EIL) can include a metal oxide such as TiO2, ZnO, ZrO, SnO2, WO3, Ta2O3, or a material doped with Al, Mg, In, Li, Ga, Cd, Cs, Cu, etc. on the metal oxide such as TiO2, ZnO, ZrO, SnO2, WO3, Ta2O3, but the present disclosure is not limited thereto.

The electron injection layer (EIL) can be omitted.

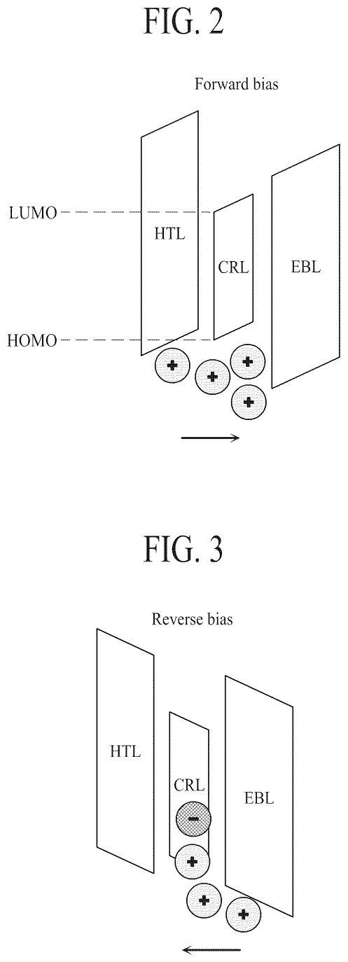

FIG. 2 is a schematic mimetic diagram of an electroluminescent display device according to an embodiment of the present disclosure when a forward bias is driven. FIG. 3 is a schematic mimetic diagram of an electroluminescent display device according to an embodiment of the present disclosure when a reverse bias is driven.

As illustrated in FIG. 2 and FIG. 3, the charge relaxation layer (CRL) can be disposed between the hole transporting layer (HTL) and the electron blocking layer (EBL). Referring to FIG. 1 described above, in each of the red sub-pixel (R sub-pixel) and the green sub-pixel (G sub-pixel), the hole transporting layer (HTL) can be the second hole transporting layer (2nd HTL), and in the blue sub-pixel B sub-pixel, the hole transporting layer (HTL) can be the first hole transporting layer (1st HTL).

A HOMO level of the hole transporting layer (HTL) is higher than a HOMO level of the electron blocking layer (EBL). Also, a HOMO level of the charge relaxation layer (CRL) is higher than a HOMO level of the hole transporting layer (HTL) and the HOMO level of the electron blocking layer (EBL).

In this case, when forward bias is applied as shown in FIG. 2, even if the charge relaxation layer (CRL) having the higher HOMO level than the hole transporting layer (HTL) and the electron blocking layer (EBL) is disposed between the hole transporting layer (HTL) and the electron blocking layer (EBL), the hole can easily move from the hole transporting layer (HTL) having a relatively high HOMO level to the electron blocking layer (EBL) having a relatively low HOMO level since the HOMO level of the hole transporting layer (HTL) is higher than the HOMO level of the electron blocking layer (EBL). In particular, as described above, when the thickness of the charge relaxation layer (CRL) is formed thinly in the range of 1 nm to 3 nm, holes can easily move from the hole transporting layer (HTL) to the electron blocking layer (EBL) due to a tunneling effect.

On the other hand, as shown in FIG. 3, when reverse bias is applied, the HOMO level of the hole transporting layer (HTL) is higher than the HOMO level of the electron blocking layer (EBL), so that holes cannot easily move from the electron blocking layer (EBL) having the relatively low HOMO level to the hole transporting layer (HTL) having the relatively high HOMO level, regardless of the charge relaxation layer (CRL). At this time, as the hole that cannot move exits into the charge relaxation layer (CRL), the hole meets free electron present in the charge relaxation layer (CRL) and then is dissipated.

Therefore, according to an embodiment of the present disclosure, when forward bias is applied, there is no problem or issue in charge movement, so that the image can be displayed. And, when reverse bias is applied, residual charges can be reduced, thereby improving the stability of the device.

The HOMO level of the hole transporting layer (HTL) can be in the range of −5.8 eV to −5.5 eV. The HOMO level of the electron blocking layer (EBL) can be in the range of −6.0 eV to −5.8 eV. The HOMO level of the charge relaxation layer (CRL) can be in the range greater than −5.8 eV and less than −4.5 eV.

Also, a LUMO level of the charge relaxation layer (CRL) can be lower than a LUMO level of the hole transporting layer (HTL) and a LUMO level of the electron blocking layer (EBL). Specifically, the LUMO level of the charge relaxation layer (CRL) can be in the range of −5.5 to −2.0 eV.

As described above, the LUMO level of the charge relaxation layer (CRL) can be lower than the LUMO level of the hole transporting layer (HTL) and the LUMO level of the electron blocking layer (EBL), and the HOMO level of the charge relaxation layer (CRL) can be higher than the HOMO level of the hole transporting layer (HTL) and the HOMO level of the electron blocking layer (EBL). Accordingly, the band gap energy of the charge relaxation layer (CRL) can be smaller than the band gap energy of the hole transporting layer (HTL) and the band gap energy of the electron blocking layer (EBL). Specifically, the band gap energy of the charge relaxation layer (CRL) can be in the range of 1.9 eV to 2.3 eV.

Specific materials of the charge relaxation layer (CRL) having the HOMO level, the LUMO level, and the band gap energy range can include, for example, rubrene and LiQ. In the case of rubrene, the HOMO level is −5.4 eV, the LUMO level is −3.2 eV, and the band gap energy is 2.2 eV. In the case of LiQ, the HOMO level is −5.4 eV, the LUMO level is −3.5 eV, and the band gap energy is 1.9 eV.

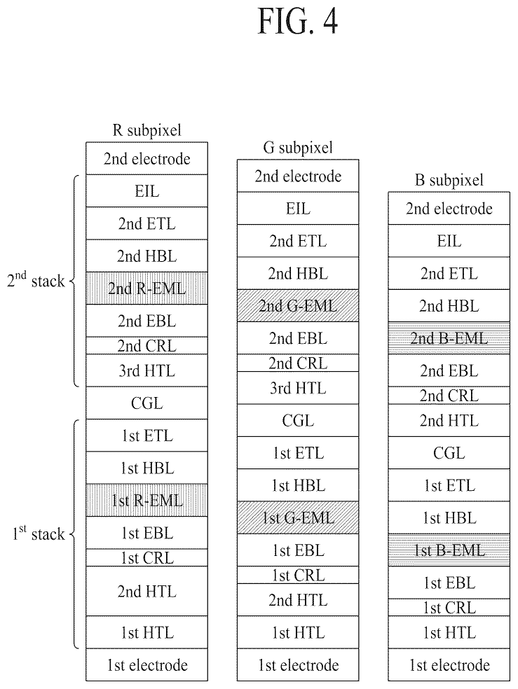

FIG. 4 is a schematic cross-sectional view of the electroluminescent display device according to another embodiment of the present disclosure, which relates to a tandem structure.

As shown in FIG. 4, the electroluminescent display device according to another embodiment of the present disclosure includes a red sub-pixel (R sub-pixel), a green sub-pixel (G sub-pixel), and a blue sub-pixel (B sub-pixel).

Each of the red sub-pixel (R sub-pixel), the green sub-pixel (G sub-pixel), and the blue sub-pixel (B sub-pixel) includes a first electrode (1st electrode), a first stack (1st stack) disposed on the first electrode (1st electrode), a charge generation layer (CGL) disposed on the first stack (1st stack), a second stack (2nd stack) disposed on the charge generation layer (CGL), and a second electrode (2nd electrode) disposed on the second stack (2nd stack).

The first electrode (1st electrode) and the second electrode (2nd electrode) of FIG. 4 are the same as those described in FIG. 1.

The first stack (1st stack) of the red sub-pixel (R sub-pixel) can include a first hole transporting layer (1st HTL), a second hole transporting layer (2nd HTL), a first charge relaxation layer (1st CRL), a first electron blocking layer (1st EBL), a first light emitting layer (1st R-EML), a first hole blocking layer (1st HBL), and a first electron transporting layer (1st ETL).

The first stack (1st stack) of the green sub-pixel (G sub-pixel) can include a first hole transporting layer (1st HTL), a second hole transporting layer (2nd HTL), a first charge relaxation layer (1st CRL), a first electron blocking layer (1st EBL), a first light emitting layer (1st G-EML), a first hole blocking layer (1st HBL), and a first electron transporting layer (1st ETL).

The first stack (1st stack) of the blue sub-pixel (B sub-pixel) can include a first hole transporting layer (1st HTL), a first charge relaxation layer (1st CRL), a first electron blocking layer (1st EBL), a first light emitting layer (1st B-EML), a first hole blocking layer (1st HBL), and a first electron transporting layer (1st ETL).

The structure of the first stack (1st stack) of each of the red sub-pixel (R sub-pixel), the green sub-pixel (G sub-pixel), and the blue sub-pixel (B sub-pixel) can be the same as the hole transporting layers (1st HTL and 2nd HTL), the charge relaxation layer (CRL), the electron blocking layer (EBL), the light emitting layer (R-EML, G-EML, B-EML), the hole blocking layer (HBL), and the electron transporting layer (ETL) described above in FIG. 1

The second stack (2nd stack) of the red sub-pixel (R sub-pixel) can include a third hole transporting layer (3rd HTL), a second charge relaxation layer (2nd CRL), a second electron blocking layer (2nd EBL), a second light emitting layer (2nd R-EML), a second hole blocking layer (2nd HBL), a second electron transporting layer (2nd ETL), and an electron injection layer (EIL).

The second stack (2nd stack) of the green sub-pixel (G sub-pixel) can include a third hole transporting layer (3rd HTL), a second charge relaxation layer (2nd CRL), a second electron blocking layer (2nd EBL), a second light emitting layer (2nd G-EML), a second hole blocking layer (2nd HBL), a second electron transporting layer (2nd ETL), and an electron injection layer (EIL).

The second stack (2nd stack) of the blue sub-pixel (B sub-pixel) can include a second hole transporting layer (2nd HTL), a second charge relaxation layer (2nd CRL), a second electron blocking layer (2nd EBL), a second light emitting layer (2nd B-EML), a second hole blocking layer (2nd HBL), a second electron transporting layer (2nd ETL), and an electron injection layer (EIL).

The second charge relaxation layer (2nd CRL), the second electron blocking layer (2nd EBL), the second light emitting layer (2nd R-EML, 2nd G-EML, 2nd B-EML), the second hole blocking layer (2nd HBL), the second electron transporting layer (2nd ETL), and the electron injection layer (EIL) can be the same as the charge relaxation layer (CRL), the electron blocking layer (EBL), the light emitting layer (R-EML, G-EML, B-EML), the hole blocking layer (HBL), the electron transporting layer (ETL), and the electron injection layer (EIL) described above in FIG. 1.

The red sub-pixel (R sub-pixel) and the green sub-pixel (G sub-pixel) can include a third hole transport layer (3rd HTL) disposed between the charge generation layer (CGL) and the second charge relaxation layer (2nd CRL). Also, a second hole transporting layer (2nd HTL) can be disposed between the charge generation layer (CGL) of the blue sub-pixel (B sub-pixel) and the second charge relaxation layer (2nd CRL) of the blue sub-pixel (B sub-pixel). However, the red sub-pixel (R sub-pixel) and the green sub-pixel (G sub-pixel) can include a hole transporting layer (HTL) which has a two-layer structure and is disposed between the charge generation layer (CGL) and the second charge relaxation layer (2nd CRL).

Meanwhile, in FIG. 4, the first charge relaxation layer (1st CRL) is disposed in the first stack (1st stack) of each of the red sub-pixel (R sub-pixel), the green sub-pixel (G sub-pixel), and the blue sub-pixel (B sub-pixel), and the second charge relaxation layer (2nd CRL) is disposed in the second stack (2nd stack) of each of the red sub-pixel (R sub-pixel), the green sub-pixel (G sub-pixel), and the blue sub-pixel (B sub-pixel), but the present disclosure is not limited thereto. For example, only one of the first charge relaxation layer (1st CRL) and the second charge relaxation layer (2nd CRL) can be disposed in each of the red sub-pixel (R sub-pixel), the green sub-pixel (G sub-pixel), and the blue sub-pixel (B sub-pixel).

The charge generation layer (CGL) can include an N-type charge generation layer disposed on the first stack (1st stack) to supply electrons to the first stack (1st stack) and a P-type charge generation layer disposed on the N-type charge generation layer to supply holes to the second stack (2nd stack).

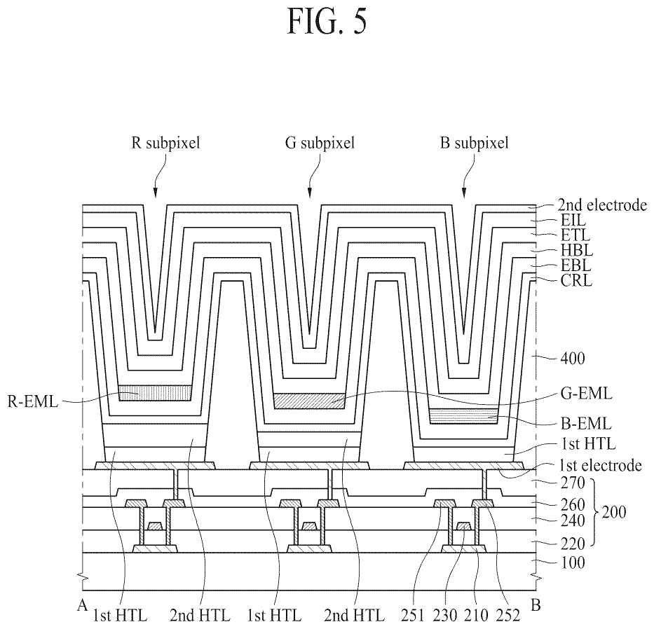

FIG. 5 is a schematic cross-sectional view of the electroluminescent display device according to another embodiment of the present disclosure.

As shown in FIG. 5, the electroluminescence display device according to another embodiment of the present disclosure can include a substrate 100, a circuit element layer 200, a bank 400, a first electrode (1st electrode), a hole transporting layer (1st HTL, 2nd HTL), a charge relaxation layer (CRL), an electron blocking layer (EBL), a light emitting layer (R-EML, G-EML), a hole blocking layer (HBL), an electron transporting layer (ETL), an electron injection layer (EIL), and a second electrode (2nd electrode).

The substrate 100 can be made of glass or transparent plastic, but is not limited thereto and can be made of a semiconductor material such as a silicon wafer. When the electroluminescent display device according to the embodiment of the present disclosure is a top emission type, not only a transparent material but also an opaque material can be used as the material of the substrate 100. However, when the electroluminescent display device according to the embodiment of the present disclosure is a bottom emission type, a transparent material is used as a material of the substrate 100.

The circuit element layer 200 is disposed on the substrate 100. The circuit element layer 200 includes a driving thin film transistor.

The driving thin film transistor includes an active layer 210 disposed on the substrate 100, a gate insulating film 220 disposed on the active layer 210, a gate electrode 230 disposed on the gate insulating film 220, a interlayer insulating film 240 disposed on the gate electrode 230, and a source electrode 251 and a drain electrode 252 which is disposed on the interlayer insulating film 240 and is connected with the active layer 210 through holes in the interlayer insulating film 240 and the gate insulating film 220. Although the driving thin film transistor having a top gate structure in which the gate electrode 230 is disposed on the active layer 210 is illustrated in the drawing, the present disclosure can include the driving thin film transistor having a bottom gate structure in which the gate electrode 230 is disposed under the active layer 210.

The circuit element layer 200 can further include a passivation layer 260 and a planarization layer 270 disposed on the driving thin film transistor. The passivation layer 260 is disposed on the source electrode 251 and the drain electrode 252, and the planarization layer 270 is disposed on the passivation layer 260.

The passivation layer 260 and the planarization layer 270 can include a contact hole, and the first electrode (1st electrode) can be connected with the drain electrode 252 through the contact hole. In some cases, the first electrode (1st electrode) can be connected with the source electrode 251 through the contact hole.

Meanwhile, in addition to the driving thin film transistor, the circuit element layer 200 can additionally include various signal lines including a gate line, a data line, a power line, and a reference line, various thin film transistors including a switching thin film transistor and a sensing thin film transistor, and a capacitor.

The switching thin film transistor is switched according to a gate signal supplied to the gate line and supplies a data voltage supplied from the data line to the driving thin film transistor.

The driving thin film transistor is switched according to the data voltage supplied from the switching thin film transistor. And, the driving thin film transistor generates a data current from a power source supplied from a power line and supplies the data current to the first electrode (1st electrode).

The sensing thin film transistor senses a threshold voltage deviation of the driving thin film transistor that causes image quality deterioration. In addition, the sensing thin film transistor supplies a current of the driving thin film transistor to a reference line in response to a sensing control signal supplied from the gate line or a separate sensing line.

The capacitor maintains the data voltage supplied to the driving thin film transistor for one frame, and is connected with a gate terminal and a source terminal of the driving thin film transistor, respectively.

Each of the switching thin film transistor, the driving thin film transistor, and the sensing thin film transistor can be changed to various structures known in the art, such as a bottom gate structure or a top gate structure.

The bank 400 is disposed on the circuit element layer 200 and is disposed in a boundary region between a plurality of sub-pixels (R sub-pixel, G sub-pixel, B sub-pixel). The bank 400 can cover both ends of the first electrode (1st electrode), and a light emitting area can be defined by the bank 400.

Detailed stack structures and constituent materials of the first electrode (1st electrode), the hole transporting layer (1st HTL, 2nd HTL), the charge relaxation layer (CRL), the electron blocking layer (EBL), the light emitting layers (R-EML, G-EML, B-EML), the hole blocking layer (HBL), the electron transporting layer (ETL), the electron injection layer (EIL), and the second electrode (2nd electrode) are the same as those described above with reference to FIG. 1, and thus, repeated description thereof will be omitted. Hereinafter, only pattern structures of these components will be described.

The first electrode (1st electrode), the hole transporting layers (1st HTL, 2nd HTL), and the light emitting layers (R-EML, G-EML, and B-EML) can be patterned in each of the plurality of sub-pixels (R sub-pixels, G sub-pixels, and B-EML). However, the first hole transporting layer (1st HTL) can be formed to be continuous in the entire boundary region between the plurality of sub-pixels (R sub-pixels, G sub-pixels, and B sub-pixels). Accordingly, the first hole transporting layer (1st HTL) can be disposed on an entire upper surface of the bank 400.

The charge relaxation layer (CRL), the electron blocking layer (EBL), the hole blocking layer (HBL), the electron transporting layer (ETL), the electron injection layer (EIL), and the second electrode (2nd electrode) can be formed to be continuous in the plurality of sub-pixels (R sub-pixel, G sub-pixel, B sub-pixel) and the entire boundary region between the plurality of sub-pixels (R sub-pixel, G sub-pixel, B sub-pixel). Accordingly, the charge relaxation layer (CRL), the electron blocking layer (EBL), the hole blocking layer (HBL), the electron transporting layer (ETL), the electron injection layer (EIL), and the second electrode (2nd electrode) can be disposed on the entire upper surface of the bank 400.

Meanwhile in FIG. 5, the tandem structure as shown in FIG. 4 can be applied instead of the structure of FIG. 1 described above.

In this case, the first electrode (1st electrode), the hole transporting layers (1st HTL, 2nd HTL, 3rd HTL), and the light emitting layers (R-EML, G-EML, B-EML) can be patterned in each of the plurality of sub-pixels (R sub-pixel, G sub-pixel, B sub-pixel). However, the first hole transporting layer (1st HTL) or the third hole transporting layer (3rd HTL) can be formed to be continuous in the plurality of sub-pixels (R sub-pixels, G sub-pixels, B sub-pixels) and the entire boundary region between the plurality of sub-pixels (R sub-pixels, G sub-pixels, B sub-pixels). Accordingly, the first electrode (1st electrode), the hole transporting layers (1st HTL, 2nd HTL, 3rd HTL), and the light emitting layers (R-EML, G-EML, B-EML) can be disposed on the entire upper surface of the bank 400.

In addition, the first and second charge relaxation layers (1st CRL, 2nd CRL), the first and second electron blocking layers (1st EBL, 2nd EBL), the first and second hole blocking layers (1st HBL, 2nd HBL), the first and second electron transport layers (1st ETL, 2nd ETL), the electron injection layer (EIL), and the second electrode (2nd electrode) can be formed to be continuous in the plurality of sub-pixels (R sub-pixel, G sub-pixel, B sub-pixel) and the entire boundary region between the plurality of sub-pixels (R sub-pixel, G sub-pixel, B sub-pixel). Accordingly, the first and second charge relaxation layers (1st CRL, 2nd CRL), the first and second electron blocking layers (1st EBL, 2nd EBL), the first and second hole blocking layers (1st HBL, 2nd HBL), the first and second electron transport layers (1st ETL, 2nd ETL), the electron injection layer (EIL), and the second electrode (2nd electrode) can be disposed on the entire upper surface of the bank 400.

Although the embodiments of the present disclosure have been described in more detail with reference to the accompanying drawings, the present disclosure is not necessarily limited to these embodiments, and can be variously modified without departing from the technical idea of the present disclosure. Therefore, the embodiments disclosed in the present disclosure are not intended to limit the technical idea of the present disclosure, but to explain, and the scope of the technical idea of the present disclosure is not limited by these embodiments. Therefore, it should be understood that the above-described embodiments are exemplary and not limited in all respects. The scope of protection of the present disclosure should be interpreted by the claims, and all technical ideas within the equivalent scope should be interpreted as being included in the scope of the present disclosure.

What is claimed is:

1. An electroluminescent display device comprising:
a first electrode;
a hole transporting layer disposed on the first electrode;
a charge relaxation layer disposed on the hole transporting layer;
an electron blocking layer disposed on the charge relaxation layer;
a light emitting layer disposed on the electron blocking layer;
an electron transporting layer disposed on the light emitting layer; and
a second electrode on the electron transporting layer,
wherein the charge relaxation layer is disposed between the hole transporting layer and the electron blocking layer to remove a residual charge.

2. The electroluminescent display device of claim 1, wherein the charge relaxation layer removes the residual charge by applying a reverse bias.

3. The electroluminescent display device of claim 1, wherein an upper surface of the charge relaxation layer is in contact with a lower surface of the electron blocking layer, and a lower surface of the charge relaxation layer is in contact with an upper surface of the hole transporting layer.

4. The electroluminescent display device of claim 1, wherein a thickness of the charge relaxation layer is in a range of about 1 nm to about 3 nm.

5. The electroluminescent display device of claim 1, wherein a Highest Occupied Molecular Orbital (HOMO) level of the hole transporting layer is higher than a HOMO level of the electron blocking layer, and
a HOMO level of the charge relaxation layer is higher than the HOMO level of the hole transporting layer and the HOMO level of the electron blocking layer.

6. The electroluminescent display device of claim 5, wherein the HOMO level of the hole transporting layer is in a range of about −5.8 eV to about −5.5 eV,
the HOMO level of the electron blocking layer is in a range of about −6.0 eV to about −5.8 eV, and
the HOMO level of the charge relaxation layer is greater than about −5.8 eV and less than about −4.5 eV.

7. The electroluminescent display device of claim 1, wherein a Lowest Unoccupied Molecular Orbital (LUMO) level of the charge relaxation layer is lower than a LUMO level of the hole transporting layer and a LUMO level of the electron blocking layer.

8. The electroluminescent display device of claim 7, wherein the LUMO level of the charge relaxation layer is in a range of about −5.5 eV to about −2.0 eV.

9. The electroluminescent display device of claim 1, wherein a band gap energy of the charge relaxation layer is less than a band gap energy of the hole transporting layer and a band gap energy of the electron blocking layer.

10. The electroluminescent display device of claim 9, wherein the band gap energy of the charge relaxation layer is in a range of about 1.9 eV to about 2.3 eV.

11. The electroluminescent display device of claim 1, wherein the hole transporting layer includes:
a first hole transporting layer disposed on the first electrode; and
a second hole transporting layer disposed on the first hole transporting layer, and
wherein the charge relaxation layer is disposed between the second hole transporting layer and the electron blocking layer.

12. The electroluminescent display device of claim 1, wherein the charge relaxation layer includes rubrene or LiQ.

13. The electroluminescent display device of claim 1, further comprising a first stack, a charge generation layer, and a second stack sequentially stacked between the first electrode and the second electrode,
wherein the hole transporting layer, the charge relaxation layer, the electron blocking layer, the light emitting layer, and the electron transporting layer are disposed in at least one of the first stack and the second stack.

14. An electroluminescent display device comprising:
a substrate including a first sub-pixel and a second sub-pixel;
a circuit element layer disposed on the substrate;
a first electrode disposed on the circuit element layer;
a hole transporting layer disposed on the first electrode and including a first hole transporting layer and a second hole transporting layer;
a charge relaxation layer disposed on the hole transporting layer;
an electron blocking layer disposed on the charge relaxation layer;
a light emitting layer disposed on the electron blocking layer;
an electron transporting layer disposed on the light emitting layer; and
a second electrode on the electron transporting layer,
wherein the charge relaxation layer is disposed between the second hole transporting layer and the electron blocking layer in the first sub-pixel, and
wherein the charge relaxation layer is disposed between the first hole transporting layer and the electron blocking layer in the second sub-pixel.

15. The electroluminescent display device of claim 14, wherein the charge relaxation layer is continuously disposed in the first sub-pixel, the second sub-pixel, and an entire boundary region between the first sub-pixel and the second sub-pixel.

16. The electroluminescent display device of claim 14, wherein a thickness of the charge relaxation layer is in a range of about 1 nm to about 3 nm.

17. The electroluminescent display device of claim 14, wherein a Highest Occupied Molecular Orbital (HOMO) level of the first hole transporting layer and a HOMO level of the second hole transporting layer are higher than a HOMO level of the electron blocking layer, and
a HOMO level of the charge relaxation layer is higher than the HOMO level of the first hole transporting layer, the HOMO level of the second hole transporting layer and the HOMO level of the electron blocking layer.

18. The electroluminescent display device of claim 14, wherein a Lowest Unoccupied Molecular Orbital (LUMO) level of the charge relaxation layer is lower than a LUMO level of the first hole transporting layer, a LUMO level of the second hole transporting layer and a LUMO level of the electron blocking layer.

19. The electroluminescent display device of claim 14, wherein a band gap energy of the charge relaxation layer is less than a band gap energy of the first hole transporting layer, a band gap energy of the second hole transporting layer and a band gap energy of the electron blocking layer.

20. The electroluminescent display device of claim 14, wherein the first sub-pixel is a red sub-pixel or a green sub-pixel, and the second sub-pixel is a blue sub-pixel.
